(19) United States
(12) Patent Application Publication
(10) Pub. No.: US 2006/0014363 A1
(43) Pub. Date: Jan. 19, 2006

(54) Thermal treatment of a semiconductor layer

(76) Inventors: Nicolas Daval, Grenoble (FR); Takeshi Akatsu, St. Nazaire les Eymes (FR); Nguyet-Phuong Nguyen, Grenoble (FR); Olivier Rayssac, Grenoble (FR); Konstantin Bourdelle, Crolles (FR)

Correspondence Address: WINSTON & STRAWN LLP, 1700 K STREET, N.W., WASHINGTON, DC, 20006, US

(21) Appl. No.: 11/233,318

(22) Filed: Sep. 21, 2005

Related U.S. Application Data
(63) Continuation of application No. PCT/FR05/00541, filed on Mar. 7, 2005.
(63) Continuation-in-part of application No. 11/058,992, filed on Feb. 16, 2005.
(63) Continuation-in-part of application No. 11/059,122, filed on Feb. 16, 2005.

(30) Foreign Application Priority Data
Mar. 5, 2004 (FR) FR 0402340
Sep. 21, 2004 (FR) FR 0409980

(51) Int. Cl. H01L 21/30; H01L 21/46

(52) U.S. Cl. 438/455

(57) ABSTRACT

A method for forming a structure that includes a layer that is removed from a donor wafer that has a first layer made of a semiconductor material containing germanium. The method includes the steps of forming a weakness zone in the thickness of the first layer; bonding the donor wafer to a host wafer; and supplying energy so as to weaken the donor wafer at the level of the zone of weakness. The zone of weakness is formed by subjecting the donor wafer to a co-implantation of at least two different atomic species, while the bonding is carried out by performing a thermal treatment at a temperature between 300° C. and 400° C. for a duration of from 30 minutes to four hours.

### CROSS-REFERENCE TO RELATED APPLICATIONS

This application is a continuation of International application PCT/FR2005/000541 filed Mar. 7, 2005 and a continuation-in-part of application Ser. Nos. 11/058,992 and 11/059,122, each filed Feb. 16, 2005. The entire content of each prior application is expressly incorporated herein by reference thereto.

### FIELD OF THE INVENTION

The invention relates to a method of forming a structure comprising a layer taken off or transferred from a donor wafer, where the donor wafer comprises, before taking off or transferring, a first layer made of a semi-conductor material comprising germanium. The method generally comprises the successive steps of forming a weakness zone in the thickness of said first layer comprising germanium; bonding the donor wafer to a host wafer; supplying energy so as to weaken the donor wafer at the level of the weakness zone. This energy supply may lead to disunite or detach the layer from the donor wafer at the level of the weakness zone and thus to take off or transfer this layer. Also, if desired, the transferred layer may be treated as necessary for the intended application of the resulting structure that includes the layer.

### BACKGROUND OF THE INVENTION

A preferred type of layer transfer is called SMART-CUT® and this method is well known to those of ordinary skill in the art. In particular, the details of such a process may be found in many documents that have already been published, such as for example the extract on pages 50 and 51 of the work “Silicon on Insulator technology: material tools VLSI, second edition,” by Jean-Pierre Colinge published by “Kluwer Academic Publishers”.

A first step that is generally carried out is the simple implantation of a single atomic species (for example of hydrogen) or by co-implantation of at least two different atomic species (for example hydrogen and helium) with suitable implantation dose and energy of the species to be implanted. This is followed by the bonding of the donor wafer to the host wafer, typically where the surface of the donor wafer that has undergone the implantation being provided with a bonding layer made of dielectric material such as SiO₂. The bonding techniques typically used by those skilled in the art include initial bonding by molecular adhesion. We can refer to the document “Semiconductor Wafer Bonding Science and Technology” (QY Tong and U. Gosele, Wiley Interscience Publication, Johnson Wiley and Sons, Inc.) to obtain more information on this step if necessary.

In a third step, energy is provided in the form of heat in order to weaken the donor wafer at the level of the weakness zone. This energy supply is susceptible to lead to the disunion of the layer from the donor wafer at the level of the weakness zone to this transfer it to the host wafer. A complementary supply of energy, in thermal and/or mechanical form, may however be necessary to effectively realize detachment of the layer to thud transfer it onto the host wafer.

In this way, a semiconductor on insulator structure (SeOI) may be formed, such as a silicon on insulator (SOI) structure (in the case of the detached layer being made of silicon), SiGeOI (in the case of the detached layer being made of germanium silicon), GeOI (in the case of the detached layer being made of germanium), SGOI (in the case of the detached layer comprising a SiGe layer on which lies a strained silicon layer), or sSOI (in the case of the taken-off layer is made of strained silicon).

It can be frequently observed that after detachment of the detached layer, the latter may have quite a rough surface, as well a lower quality crystalline structure on its surface, notably due to the fact that the implantation and the detachment steps have taken place beforehand.

In reference to FIG. 1, a semiconductor on insulator structure 30 is shown diagrammatically (composed of a host wafer 20 covered by the detached layer 1 by means of an electrically isolating layer 5), which has, in its semiconductor part (i.e. the detached layer 1), such a reduction in the crystalline quality. It may be observed that the detached layer 1 comprises a defective zone 1A, this defective zone 1A comprising existing crystalline defects and surface roughness. The defective zone 1A typically has a thickness of around 150 nm for an atomic implantation of hydrogen. Furthermore, the implantation step may have caused a reduction of the crystalline quality of the detached layer 1. An additional step of treating the detached layer 1 is therefore necessary to remove this defective zone 1A, and thus recuperate at least part of the sound zone 1B of the layer taken 1. For example, it is possible to use mechanical polishing or chemical-mechanical polishing (CMP) to eliminate the surface roughness, and/or sacrificial oxidation steps of the defective zone 1A. By sacrificial oxidation, one classically understands a step comprising the operations of oxidation of the defective zone and of removal of the oxide layer thus formed by chemical etching (for instance by using hydrofluoric acid HF).

By way of illustration, such a method is described in published application U.S. 2004/0053477, in which a strained silicon layer is detached from a donor wafer comprising a SiGe buffer layer. The first step includes the implantation of atomic species into the buffer layer, and the last step comprises the removal of the part detached from the buffer layer by means of surface polishing the SiGe, followed by the selective etching of the SiGe with respect to the strained Si. The selective etching enables the desired layer to be obtained with a good quality of surface finish, without too high a risk of damaging it (as could be the case if only polishing were used). However, the chemical etching used in this step (d) may in certain cases lead to at least partial detachment problems of the bonding interface (bonding carried out in step (b). Indeed, the chemical etching of step (d) may in particular cause de-lamination at the edge of the bonding layer, which is to say attack the latter where it touches by the slice of the structure created. For example, we can mention the case of a HF treatment on an sSOI (strained Silicon on Insulator) structure comprising SiO₂, buried under the strained Si, or the case of a H₂O₂:HF:HAc treatment (HAc being the abbreviation of acetic acid) on a SGOI structure (Strained Silicon on Silicon Germanium On Insulator), where the buried SiGe and SiO₂ layers are likely to be etched under the strained Si layer.

An alternative that could be used to overcome the last problem would be to dilute the etching solution considerably so that its action is easier to control. However this solution is not satisfactory due to the fact that it does not totally resolve the de-lamination problem and that the method is slightly slowed down. Moreover, this chemical etching requires prior preparation of the surface to be etched, typically carried out using mechanical polishing means. In fact, this etching preparation remains necessary to correct part of the major roughness which could subsequently lead to etching that is not sufficiently homogeneous and likely to create traversing defects or holes in the remaining layer, but also lead to the free face of the final product being rough. Furthermore, the presence of defects in the whole thickness of the taken-off layer (and not only in the thickness of the defective zone) is also likely to cause an inhomogeneous etching.

But successive actions of polishing and chemical etching make the post-detachment finishing step (as well as the entire sampling method) long, complex and costly from an economic point of view. Of course, it will be understood that problems encountered when a selective etching is performed are relatively similar to those encountered when performing an etching operation during a sacrificial oxidation, in particular as concerns the etching inhomogeneity due to a superficial roughness and a presence of defects. However, there is a need for improvements in these type treatments and these are now provided by the present invention.

### SUMMARY OF THE INVENTION

The invention now provides a method which reduces the duration, the economic cost and the number of treatment means during the treatment step of a transferred layer, and in particular to avoid the use of mechanical polishing. This facilitates the formation of a structure, such as a SeOI semiconductor on insulator structure, by transferring a layer of a semiconductor material comprising germanium, such as, in particular, a SiGe layer. The resulting transferred layer is of much better quality that those provided by the processes of the prior art. This also results in a reduction in the quantity of material that is removed treating the transfer layer. Thus, the to proposes a simple method of treating the transfer layer that can easily be incorporated into a SMART-CUT® type method.

In particular, the invention relates to a method of forming a semiconductor structure, which comprises forming a zone of weakness in a donor wafer made of a semiconductor material comprising germanium to define a layer that includes germanium to be transferred, by co-implanting at least two different atomic species into the donor wafer; bonding the donor wafer to a host wafer to form a combined structure; and supplying energy to the donor wafer by performing a thermal treatment at a temperature between 300° C. and 400° C. for a period of from 30 minutes to four hours to weaken the donor wafer at the zone of weakness for subsequent transfer to the host wafer. The amount of energy provided can be sufficient to transfer the layer or instead a separate application of mechanical or additional thermal energy can be provided for that purpose.

By this method, the resulting surface smoothness of the transfer layer is enhanced and typically the transfer layer has low/high frequency roughnesses that are lower than about 15 Å RMS/30 Å RMS, respectively, when measured by 500 micron profilometry/2*2 μm² AFM.

Another aspect of the invention relates to the resulting semiconductor on insulator structure that comprises a surface layer bonded to a host wafer with the surface layer having the previously mentioned properties at any place on its surface.

### BRIEF DESCRIPTION OF THE FIGURES

Other characteristics, aims and advantages of the invention will become clear upon reading the following detailed description of the application of preferred methods of it, given by way of non-restrictive examples and made in reference to the appended diagrams in which:

FIG. 1 shows a diagrammatical cross section of a semiconductor on insulator structure obtained after the application of a SMART-CUT® method according to the prior art.

FIG. 2 shows a cross sectional view obtained by TEM by the applicant of a semiconductor on insulator structure obtained after application of the method of the invention.

FIGS. 3a to 3e show diagrammatically the different steps of a method of the invention to form a structure comprising a layer taken using SMART-CUT®.

FIGS. 4a and 4b show diagrammatically a first variant according to the invention.

FIGS. 5a and 5b show diagrammatically a second variant according to the invention.

FIG. 6 illustrates the presence of pores type defects in a structure for which a post disunion thermal treatment at 600° C. has been carried out

### DETAILED DESCRIPTION OF THE INVENTION

As noted, the invention relates to a method of forming a structure comprising a layer that is detached from a donor wafer, the donor wafer comprising prior to detachment a first layer made of a semiconductor material comprising germanium. Preferably, the method comprises the following steps:
(a) formation of a weakness zone in the thickness of the layer comprising germanium
(b) bonding the donor wafer to a host wafer; and
(c) supplying energy so as to weaken the donor wafer at the level of the weakness zone. Step (a) is advantageously carried out by subjecting the donor wafer to co-implantation of at least two different atomic species, while step (c) is advantageously carried out by performing a thermal treatment at a temperature between 300° C. and 400° C., for a duration that can last up from 30 minutes to four hours.

Other potential characteristics of the method according to the invention are as follows:

The thermal treatment of step (c) is preferably carried out at a temperature of between 325° C. and 375° C. for approximately two hours. The energy supply in step (c) may be sufficient to lead to the disunion or detachment of the donor wafer at the level of the weakness zone and thus to the detachment and transfer of that layer to the host wafer. Alternatively, after step (c), the method instead comprises a step of supplying a complementary thermal or mechanical energy adapted to detach the donor wafer layer at the level of the weakness zone.

In another embodiment, before step (b), the method further comprises a step of plasma activation of one or both of the wafer surfaces to strengthen the bonding of the wafers.

The co-implantation of step (a) is preferably a co-implantation of helium and hydrogen, with the doses of helium and hydrogen chosen so that the helium dose represents 30% to 70% of the total dose, and preferably 40% to 60% of the total dose with the hydrogen dose representing the remainder of the total dose.

Preferably, the transfer layer has low/high frequencies roughnesses, after detachment from the donor wager at the level of the weakness zone, which are lower than around 15 Å RMS/30 Å RMS, respectively, measured by 500 microns profilometry/2*2 μm² AFM.

In another embodiment, the method further comprises a step (d) adapted for treating the transferred layer. This step (d) preferably comprises an etching operation of the transfer layer. This etching operation is advantageously carried out during a sacrificial oxidation of the transfer layer. Preferably, the donor wafer comprises before detachment a second layer of a material different from that of the first layer with the etching operation being a selective etching of that part of the transfer layer remaining after detachment with respect to the second layer. Before this selective etching operation, a sacrificial oxidation of at least a part of the remaining part of the transfer layer is carried out so as to remove material from the remaining part and to strengthen the bonding interface.

In yet another embodiment, the method further comprises, after step (d), growth of a crystalline material adapted to thicken the second layer that remains after transfer.

As for the materials of the layer, preferred materials include a layer made of Si₁₋ₓGeₓ with 0<x≦1 with the donor wafer comprising a second layer made of elastically strained Si. Alternatively, the donor wafer may comprise a support substrate made of bulk Si, a buffer structure made of SiGe, a first layer comprising Si₁₋ₓGeₓ with 0<x≦1 (i.e., x ≠0) and a second layer made of strained Si. A further alternative is a first layer made of Si₁₋ₓGeₓ and the donor wafer comprising a second layer made of strained Si and a third layer made of Si₁₋ₓGeₓ on the second layer. For the latter, step (d) may comprise a selective etching of the remaining part of the first layer with respect to the second layer.

When multiple layer transfers are to be made, the donor wafer may instead comprise a support substrate made of bulk Si, a buffer structure made of SiGe, and a multi-layer structure alternatively comprising multiple first layers of Si₁₋ₓGeₓ (x≠0) and multiple second layers made of strained Si, so as to be enable several layer transfers to be made from the same donor wafer.

The method may further comprise, prior to step (a), the formation of the strained layer at a deposit temperature of between around 450° C. (842° F.) and around 650° C. (1,202° F.).

Also, the method may further comprise, prior to step (b), a step of forming a bonding layer on the donor wafer and/or on the host wafer. This bonding layer preferably comprises an electrically insulating material such as SiO₂, Si₃N₄ or SiₓO_{y}Nₓ.

According to a second aspect of the invention, an application of the previously described method includes the formation of a semiconductor-on-insulator structure such as a sSI, SGOI, SiGeOI or GeOI structure.

According to a third aspect, the invention proposes a semiconductor on insulator structure obtained after carrying out all of the steps (a), (b) and (c) of the method according to the first aspect, and after removing the transferred layer with the remaining part of the donor wafer, this structure has a surface with low/high frequencies surface roughnesses of less than about 30ARMS, as measured by profilometry 500 μm and AFM 10×10 μm², in any place of the wafer.

Preferred examples of embodiments of methods according to the invention are described below, as well as applications according to the invention, based on layers taking-off using SMART-CUT® comprising germanium, such as SiGe layers.

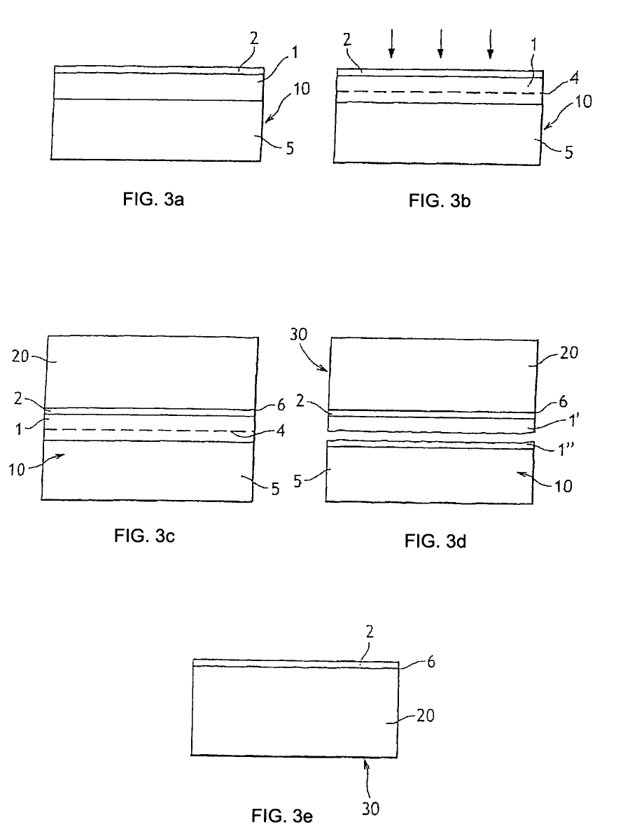

With reference to FIGS. 3a to 3e, is shown a first method of detaching a first layer 1 of Si₁₋ₓGeₓ (where x ∈[0;1]) and a second layer 2 of elastically strained Si from a donor wafer 10, to transfer them to a host wafer 20 according to the invention.

With reference to FIG. 3a, a donor wafer 10, comprising the first layer 1 made of Si₁₋ₓGeₓ and the second layer 2 of elastically strained Si, is illustrated. Classically, a donor wafer 10 including Si₁₋ₓGeₓ comprises a bulk Si substrate 5 on which has been formed for example by crystalline growth a buffer structure of SiGe (not shown) made up of different layers. In particular, the latter may have a gradual evolution in thickness in its composition of Ge, starting from 0% at the bulk Si substrate level to around 100×% at the level of the interface with the first layer 1 made of Si₁₋ₓGeₓ (it also preferably being formed by crystalline growth).

A second layer 2 of strained Si is formed on the first layer 1 in Si₁₋ₓGeₓ. In a first case, the growth of the second layer 2 is carried out in situ, directly in continuation of the formation of the first layer 1. In a second case, the growth of the second layer 2 is carried out after a light step of preparation of the surface of the underlying adaptation layer 2, for example by CMP polishing.

The second layer 2 made of Si is advantageously formed by epitaxy using known techniques such as Chemical Vapor Deposition (CVD) and Molecular Beam Epitaxy (MBE) techniques. The silicon contained in the second layer 2 is then obliged by the first layer 1 to increase its nominal mesh parameter to make it more or less identical to that of its growth substrate and thus to impart internal elastic strain tensions. It is necessary to form a quite thin second layer 2: if the layer is too thick, thicker than a critical equilibrium thickness, would cause a relaxation of the strain in the film thickness towards the nominal lattice parameter of the silicon and/or generation of faults. Please refer to the document entitled “High mobility Si and Ge structures” by Friedrich Schaffler (“Semiconductor Science Technology”, 12 (1997) 1515-1549) for further details on this subject. In the particular case of a deposit of strained material at a sufficiently low temperature, however, it is possible to form such a second strained layer 2 having a more important thickness (the critical balance thickness is indeed linked to the deposit temperature: it is all the more important as the deposit is carried out at low temperature).

With reference to FIG. 3b, a zone of weakness 4 is then formed in the donor wafer 10 underneath the second layer 2. In particular, an implantation of atomic species may be performed in order to form the zone of weakness in the thickness of the first layer 1 made of Si₁₋ₓGeₓ (as it is shown in FIG. 3b). This zone of weakness 4 is formed by implantation of atomic species whose dosage, nature and energy are chosen so that a depth of implantation and a level of fragility are determined. In particular, the parameters determining the implantation of atomic types are adjusted so as to minimize the surface roughness which appears at the level of the zone of weakness 4 after detachment. In fact, the extent of the post-detachment surface roughness is partially caused by the parameters defining the implantation used, as we will subsequently see.

Thus, according to the invention, the preferred implantation of atomic species is a co-implantation of atomic species (i.e., the implantation of, principally, at least two different atomic elements), such as for example a co-implantation of two different atomic species selected from hydrogen, helium or argon or another rare gas or another suitable gas. In the case of a co-implantation, it has been observed that the zone of weakness 4 is generally thinner than in the case of a simple implantation with one atomic species. The recourse to co-implantation will especially allow to obtain a post detachment roughness that is significantly lower than that obtained when implantation is made of a singe implantation of helium or hydrogen. One finds here one of the advantages of co-implantation which allows for the taking-off of a thin layer using a total dose of co-implanted species lower than the dose to be used when a single species is implanted. The total dose in co-implantation thus typically represents ⅓ of the single species implantation dose.

The energy of the implantation is chosen so as to have an implantation depth neighboring that of the depth of the first layer 1. Thus for a co-implantation with helium of around 1.10¹⁶/cm² and energy of between 50 and 90 keV and hydrogen at 1.10¹⁶/cm² and energy of between 20 and 60 keV, we can obtain a depth of implantation of around 300 to 600 nanometers. Generally speaking, helium and hydrogen doses are chosen so that the helium dose represents 30% to 70% of the total dose, and preferably 40% to 60% of the total dose.

With reference to FIG. 3c, a bonding step of a host wafer 20 with the side of the donor wafer 10 having undergone the co-implantation is carried out. The host wafer 20 may be made of bulk Si or other materials.

Prior to the implantation step, a bonding layer may be formed, such as a layer comprising SiO₂, Si₃N₄, SiₓO_{y}N_{z} on one and/or the other of the respective surfaces to be bonded. In the case this bonding layer has to be formed onto the donor wafer, the technique used to form this bonding layer may be a deposit, in order to avoid any deterioration of the strains in the second layer 2 or any diffusion consequently in the first layer 1. Prior to bringing the host wafer 20 into contact with the donor wafer 10, the surfaces to be bonded may possibly be prepared, using known surface cleaning and polishing techniques such as SC1 and SC2 solutions, ozone solutions etc. The bonding itself may be firstly carried out by molecular adhesion, by being able to take account of the hydrophily of each of the two surfaces to be bonded.

It is also possible to use plasma activation of one or both of the two bonding surfaces just before bonding. A plasma activation permits in particular to create handling bonds, for example on an oxide surface, on the surface(s) to be treated, and therefore increase the bonding forces to be made and reduce the number of defects at the bonding interface 6, as well as their influence on the quality of the bonding. Such strengthening of the bonding interface 6 will also have the advantage of therefore making this interface much more resistant to chemical attacks from later etching (used when finishing the surface of the layer taken off, for instance during a selective etch operation or a sacrificial oxidation operation) and avoid delamination problems at the edges as previously discussed, which may typically appear for a bonding energy below approximately 0.8 J/m². In particular, the plasma activation can be used so that in the end, after bonding and after taking-off, the bonding energy is greater than or equal to approximately 0.8 J/m².

The plasma may be obtained for example from an inert gas, such as Ar or N₂, or from an oxidizing gas such as O₂. The plasma activation can typically be carried out at ambient temperature, below approximately 100° C. The use of this technique therefore also has the advantage of not causing any notable problems of diffusing Ge from the first SiGe layer 1 to the second strained Si layer (generally speaking Ge diffusion starts becoming significant in the thickness of the neighboring layers for much higher temperatures, typically around 800° C. or more). The duration of the plasma treatment is very quick, typically less than one minute. The equipment used will be for example standard plasma etching equipment of the RIE or ICP-RIE types or other.

After step (b) of bonding, energy is supplied under thermal form during step (c) in order to weaken the donor wafer at the level of the zone of weakness. It has to be noted that the thermal budget (typically temperature and length) of this energy supply (hereafter said “weakening thermal treatment”) can in particular, but not necessarily, lead to the disunion or detachment of the layer from the donor wafer at the level of the zone of weakness. The weakening thermal treatment is typically carried out at a temperature lower than 800° C., but all at least lower than a limit temperature from which the Ge diffusion in the neighboring layers becomes prejudicial.

With reference to FIG. 3d, the detachment step of the donor wafer 10 is shown with the resultant layer that is transferred having a first part 10′ comprising a remainder of the first layer 1″ and a second part 30 comprising the other part of the first layer 1′ and the second layer 2. As already mentioned above, this detachment can be performed thanks to the energy supply of the weakening thermal treatment. However, when the energy supply of the weakening thermal treatment is not sufficient to lead to the disunion, this latter can be carried out using a complementary supply of energy (for instance under thermal and/or mechanical form) sufficient to cause, at the level of the weakness zone 4, thermal effects on the gaseous types enclosed there causing the rupture of weak links. Generally speaking, detachment may be obtained at temperatures of between around 300° C. and around 600° C. for durations of varying lengths which depend on whether the temperature is lower (longer length) or higher (shorter length).

Optionally, or in replacement of the plasma activation, a thermal treatment can be carried out directly after disunion, in order to strengthen the bonding interface 6. In the case of this bonding strengthening heat treatment being used in addition to the plasma activation, it is therefore possible to make sure that the combined effects of these two treatments achieve the desired objectives, an in particular a bonding energy sufficient to make the bonding interface 6 resistant to chemical attack from later etching, and thus to avoid delamination problems on the edges, as previously described. These two treatments can be combined to strengthen the bonding interface 6 to obtain a bonding energy greater than or equal to approximately 0.8 J/m². In any case, the heat treatment for strengthening the bonding interface 6 is carried out at a temperature T₂ chosen below the temperature above which the Ge diffuses significantly into the thickness of the second layer 2.

The heat treatment to strengthen the bonding interface 6 is carried out at a temperature T₂ lower than or equal to approximately 800° C. Temperature T₂ can for instance be between 350° C. and 800° C., maintained during 30 minutes up to four hours. This bonding strengthening thermal treatment can in particular, without this being restrictive, be carried out during a step of sacrificial oxidation, during which an oxidation of the surface of the remainder of the first layer 1′ (typically SiGe layer) is carried out around 600/800° C., and then a removal of the oxide thus formed is carried out. In such a case, the sacrificial oxidation has thus for double objective to reinforce the bonding interface and to proceed to the removal of at least a part of the defective zone.

This heat treatment to strengthen the bonding is carried out in an inert atmosphere (such as an Ar or N₂ atmosphere) that is oxidizing or slightly oxidizing. It has been observed that by using such a step of bonding interface 6 strengthening, in particular when it is followed by a co-implantation step, the transfer layers then have:
an improved crystalline quality in their parts damaged during the implantation (in reference to FIG. 3b) and during detachment (in reference to FIG. 3d);
a smoothed surface, in particular for high frequency roughness (HF roughness);
a bonding energy greater than approximately 0.8 J/m² (without plasma activation).

It has to be noted that the decrease of the defective zone 1A thickness is more particularly observed when the weakness zone is formed by co-implantation. In the same way, the post detachment surface roughness is also significantly decreased when a co-implantation is performed rather than the implantation of a single species. This is mainly due to the fact, already mentioned above, that the total dose in co-implantation is much lower than the implanted dose when a single species is implanted. Thus co-implantation has the unexpected advantage, compared to the implantation of a single species, to reduce the thickness of the defective zone, which in particular makes it possible to reduce or simplify the finishing treatments implemented after detachment. In the same way, co-implantation also has the advantage of reducing roughness, which also makes it possible to facilitate the finishing treatments.

However, such a bonding strengthening heat treatment cannot be completely satisfactory. For thermal treatments carried out at 600° C. in order to strengthen the bonding interface, the presence, close to the surface, of a low density of “pores” and other types of defects have been observed. These are secondary defects consisting mainly of three-dimensional zones of low density in the material and whose size (roughly the diameter) is about 3-4 nm. The origin of the these defects is not certain, but it seems that it is related to the bonding strengthening heat treatment (typically at 500° C. or 600° C.). In addition, this bonding strengthening treatment being realized in furnaces in which the temperature is not entirely uniform (one can then observe a temperature gradient at the level of the surface of the wafer, for example a 300 mm in diameter wafer, the wafer being positioned vertically in the furnace), it may be that the distribution of defect on the surface is not homogeneous, which poses a problem to carry out an etching operation.

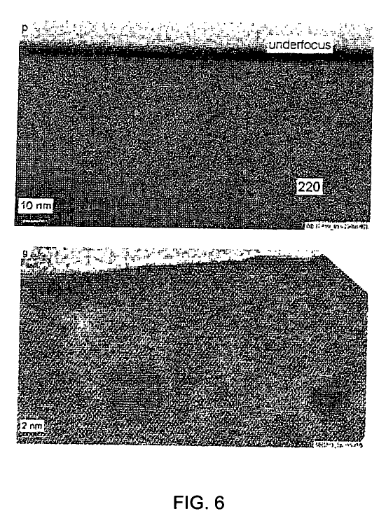

FIG. 6 shows two views obtained by TEM (respectively on a scale of 10 nm for the top view and of 2 nm for the bottom view) of an intermediate structure (intended to form a final sSI structure) which was subjected to such a post-disunion thermal treatment at 600° C. and in which pores are observed. But these crystalline defects are not desirable insofar as they are likely to locally modify etching and/or oxidation speeds during the finishing operations likely to be performed after detachment. These operations are then made more complex, or then require the implementation of a mechanical treatment aiming at carrying out a removal of material (polishing/planarization), which, as mentioned previously, is not desirable because it has an over cost and is likely to compromise the uniformity characteristics of the taken-off layer.

In order to prevent the appearance of these pores and other defects, it has been found that the step of weakening thermal treatment by carrying out a low temperature annealing, at a temperature ranging between 300° C. and 400° C., for example at approximately 350° C. (+/−25° C.), for a length of time ranging between approximately 30 minutes and approximately four hours, for example during approximately two hours. Of course, it will have been understood that as a function of the thermal budget (couple temperature/length), this treatment may or may not result in detachment of the layer from the donor wafer. If the weakening treatment does not result in detachment, a supply of complementary energy, under thermal or mechanical form, can be carried out as previously explained. Generally speaking, it is a question here of locally bringing energy (in time and/or space) per application of a mechanical tool or of a short or localized heating so as to initiate the detachment at the level of the weakness zone, detachment which then can auto-propagated. For further details, one can refer to related patent applications PCT/FR0402779 and PCT/FR0402781.

In particular, a complementary supply of energy under mechanical form can in such a case figure be a rather weak complementary supply, sufficient to initiate the detachment. It has been noted that the recourse to such a weaken treatment allows, in the case of a co-implantation, to limit the presence of defects. Results of roughnesses measurement on a SGOI structure with 20% of Ge are presented hereafter and relate to the case of a weakening heat treatment performed during approximately two hours, at a temperature substantially equal to 350° C. In these experiments, no heat treatment for post detachment bond strengthening or curing was performed. The roughness measurements were conducted both at low frequencies (realized using the DEKTAK® profilometry tool of the company Veeco Instruments Inc, 500 μm of sweeping) and at high frequencies (realized by sweeping a surface area of 2*2 μm² with the point of an atomic force microscope AFM). Results of these measurements are expressed in RMS (“Root Mean Square”) average values.

In the following table, by way of comparison, one also deferred the roughnesses measured on a identical SiGeOI structure (at 20% Ge) right after detachment caused by heating at 500° C. for 30 minutes, following single implantations or co-implantations, and a post-detachment thermal treatment for strengthening the bonding at 600° C.

| Nature of the implantation | Low Frequencies | High frequencies |
|---|---|---|
| Recovering treatment | roughness | roughness |
| H only implantation | | |
| 30 keV - 6.10¹⁶/cm² | | |
| Post-disunion treatment at | 18 Å RMS | 29.7 Å RMS |
| 600° C. during 1 h | | |
| He/H Co-Implantation | | |
| He: 56 keV - 1.10¹⁶/cm² | | |
| H: 50 keV - 1.10¹⁶/cm² | | |
| Post-disunion treatment at | 13 Å RMS | 25.6 Å RMS |
| 600° C. during 1 h | | |
| Weakening treatment at 350° C. | 12 Å RMS | 25.6 Å RMS |
| during two hours | | |

This table shows that in the case of a co-implantation, a weakening thermal treatment at 350° C. makes it possible to reach levels of low roughnesses and high frequencies equivalents with those observed for a post-disunion treatment at 600° C. However, in the case of a weakening thermal treatment at 350° C., defects of the “pores” types are not observed and a good surface defectivity uniformity is reached, and that in any place of the wafer (that is on the entirety of the diameter, typically 200 or 300 mm, of the wafer).

These good results seem in particular obtained owing to the fact that the low temperature treatment (typically around 350° C.) is likely to cause only a low amplitude temperature gradient (in comparison with that observed for a higher temperature treatment, for example at 500° C. or 600° C.) in the furnace. Thus, the detachment parameters identified here (co-implantation, low temperature weakening treatment) make it possible in particular to reduce the thickness of the defective zone, to limit the presence of defects and to minimize the surface roughness. Under such conditions, the eventual post-detachment finishing operations are facilitated; in particular, the recourse to the use of an operation of polishing/planarization is avoided or all at least limited.

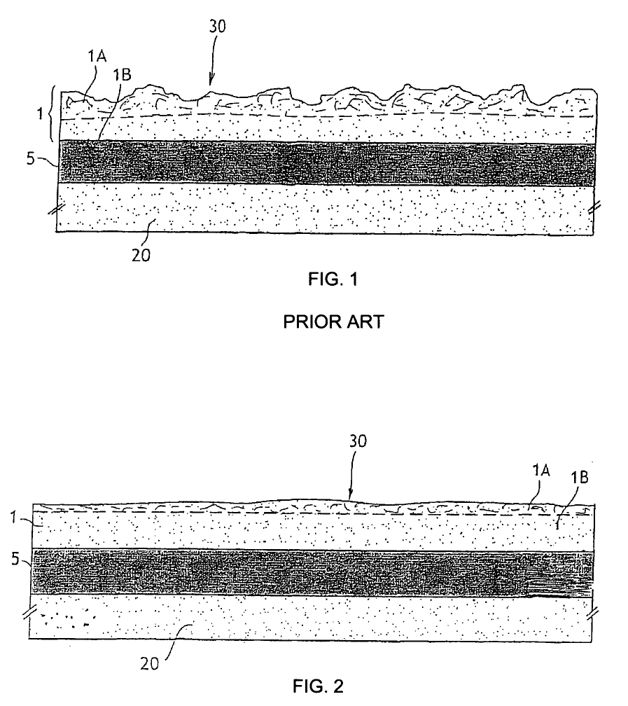

In reference to FIG. 2, a SiGeOI structure 30 with Ge 20% (photographed by TEM) obtained following a transfer of a simple layer of SiO_{0.8} Ge_{0.2} in which the weakness zone was formed, and following a weakening thermal treatment at 350° C., shows a transfer layer 1 in Si_{0.8} Ge_{0.2} (i.e. the equivalent of the said first layer 1 and second layer 2 joined together, discussed before in reference to FIGS. 3a to 3e), covers a SiO₂ layer 5 and includes very few crystalline defects and very small roughnesses (good smoothness) compared to that of the semiconductor-on-insulator structure of FIG. 1 (prior art). One will in particular notice disproportion between the thickness of the defective zone 1A of the transfer layer 1 in reference to FIG. 1 and that of the cured transfer layer 1 in reference to FIG. 2. In the same way, and for a same transfer layer thickness 1 for FIGS. 1 and 2, the healthy zone 1B is much more significant in proportion in the SiGeOI obtained according to the invention than in the semiconductor-on-insulator of the state of the art.

Returning to the description of the method illustrated by the FIGS. 3a-3e, and with reference to FIG. 3e, after withdrawal of the remaining part of the donor wafer 10′ from the contact with the transfer layers 1′ and 2, a structure 30 is obtained comprising the host wafer 20, the second layer 2 and the remaining part of the first layer 1′. This structure 30 has an improved crystalline quality and reduced roughness, without having need for an intermediate polishing operation. In particular, the remaining part of the first layer 1′ has no pores or other defects, notably close to the surface. In the case of an electrically insulating layer being formed beforehand, between the second layer 2 and the host wafer 20, then a SiGe/sSOI or Ge/sSOI structure is obtained.

A finishing step is then used to remove the slight roughness and few remaining crystalline defects at the surface, such as the use of chemical etching, for instance in the framework of a selective etching of a layer with respect to anther or of an etching carried out during a sacrificial oxidation. The mechanical polishing means used prior to the chemical etching to reduce the surface roughness (and therefore to make the different points of the etching more homogeneous), do not necessarily need to be included. Indeed the implementation of a co-implantation ensures a much smoother sampling surface than hat obtained by simple implantation.

The Si₁₋ₓGeₓ layer 1′ may possibly be removed in order to obtain a final sSOI structure (see FIG. 3a). It is then possible to make the strained silicon of this structure thicker by epitaxy. To remove the layer 1′ of Si₁₋ₓGeₓ selectively, it is possible to use selective etching by using for example HF:H₂O₂:CH₃COOH, SC1 (NH₄OH/H₂O₂/H₂O) or HNA (HF/HNO₃/H₂O). A selectivity of around 40:1 between the SiGe and the sSi may be obtained with CH₃COOH/H₂O₂/HF. An example of concentration that may be chosen for the CH₃COOH/H₂O₂/HF such that the ratio H₂O₂/HF is comprised between 1/1 (very concentrated) and 20/1. The length of the etching is directly correlated with the speed of etching. It is typically around 5 minutes for 800A to be etched with CH₃COOH/H₂O₂/HF.

Thus, the co-implantation and the use of the low temperature weakening thermal treatment having considerably reduced the surface roughness and the non-uniformities of thickness in the transfer layers 1′ and 2, it is possible to use more or less the same selective etchings as those of the state of the technique, but by also eliminating the disadvantages that they can present, such as the need to use beforehand mechanical polishing means.

In the case of one or more bonding layers being buried under the bonding interface 6, a heat treatment may possibly then be used to strengthen the bonding further, in particular by creating covalent links. This bonding strengthening heat treatment may be carried out here at a temperature of over 800° C., given that there is no more SiGe or Ge in the structure 30, and that there are therefore no more problems of diffusion of Ge (the remainder of the first layer 1′ having been completely removed).

Possibly, a subsequent step of crystalline growth may be used (for example MBE or CVD epitaxy) to thicken the second layer of strained Si.

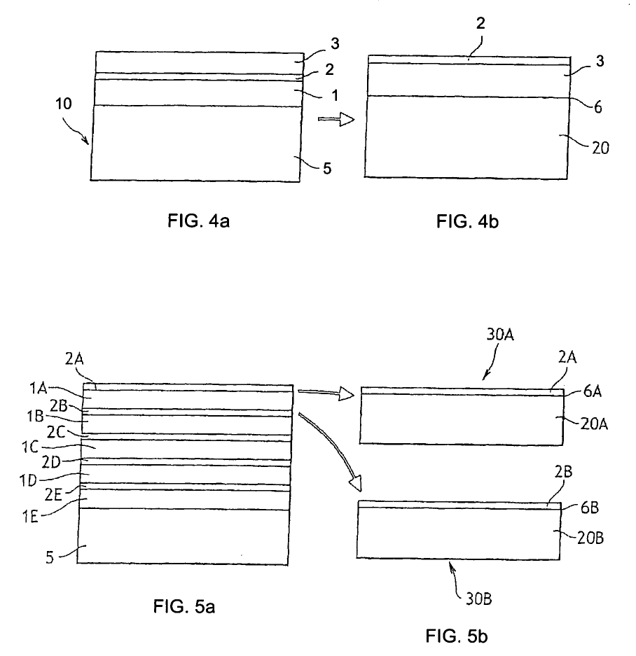

According to a second variant of the invention, with reference to FIGS. 4a and 4b, the donor wafer 10 comprises prior to taking off a first layer 1 of Si₁₋ₓGeₓ, then a second layer 2 of strained Si and a third layer 3 of Si₁₋ₓGeₓ that is situated on the second layer 2. The weakness zone is then formed according to the invention underneath the second layer 2, for example in the first layer 1. Selective etching of the Si₁₋ₓGeₓ may then be used after separation in compliance with what has been already seen, so as to create finally a SGOI structure 30 (Strained Silicon On SiGe On Insulator structure, as shown on FIG. 4b) with a first layer 1 of Si₁₋ₓGeₓ and a second layer 2 of strained Si.

Optionally, it is possible to thicken the second layer 2 of strained Si by crystalline growth.

Optionally and alternatively, a second selective chemical etching of the strained Si may be carried out, for example by means of chemical types based for example on KOH (potassium hydroxide), NH₄OH (ammonium hydroxide), TMAH (tetramethyl ammonium hydroxide) or EDP (ethylene diamine/pyrocathecol/pyrazine). In this case, the second layer 2 made of strained Si only plays the role of a stop layer protecting the third Si₁₋ₓGeₓ layer 3 from the first chemical attack. A SiGeOI structure (not shown) is then obtained. A layer of strained Si can be possibly grown on the SiGeOI, this new strained layer may then have a better quality crystalline structure than the second layer 2 which has previously been etched.

According to a third variant of the invention, in reference to FIGS. 5a and 5b, the donor wafer 10 comprises prior to taking-off a multi-layer structure alternatively comprising first layers 1A, 1B, 1C, 1D, 1E in Si₁₋ₓGeₓ(x ≠0) and second layers 2A, 2B, 2C, 2D, 2E in strained Si. We can thus carry out a number of takings-off according to the invention, from the same donor wafer 10, each taking-off being then followed by recycling of the remaining part of the donor wafer 10 in order to prepare it for a new taking-off. In this way, a first sSOI structure 30A and a second sSOI structure 30B will for example be formed from the same donor wafer 10. This type of transfer is taught in U.S. 2004/0053477.

According to one particular embodiment of the invention, each strained layer (referenced “2” in FIGS. 3a to 3e, “1” in FIGS. 4a and 4b, and “2A”, “2B”, “2C”, “2D” or “2E” in FIGS. 5a and 5b) of the donor wafer is thick, which is to say that it has a relatively important thickness without having the relaxation of its elastic strains. This has been made possible thanks to the formation by low temperature epitaxy. For example, a layer of strained Si deposited at temperatures of between approximately 450° C. and 650° C. on a growth support of Si_{0.8}Ge_{0.2} can typically reach a thickness of between approximately 30 nm and 60 nm.

If such a thick strained layer is formed in this way, then care must be taken not to exceed a certain limit temperature (which is situated around the deposit temperature) in the following treatments, and in particular the treatments occurring between the deposit of the layer and the detachment of the latter, carried out by SMART-CUT®, in order to avoid relaxing of the strains. Thus, in this case of thick strained layers, plasma activation prior to bonding (as discussed earlier) will be advantageously used and typically carried out at an ambient temperature lower than approximately 100° C. Furthermore, at least one layer of dielectric material bonding, such as SiO₂, is advantageously formed on one or both of the two surfaces to be bonded, this layer made of dielectric material subsequently helping (i.e. after separation) to conserve the elastic strains.

Of course, those skilled in the art can easily transpose the invention presented above to other materials than Si₁₋ₓGeₓ or strained Si, given that he knows the properties and physical grandeurs associated to these materials. For example, by retracing the steps previously described, in reference to FIGS. 3a to 3e, those skilled in the art could create a final structure 30 made of AsGa on insulator, if a donor wafer 10 whose first layer 1 is made of Ge and the second layer 2 made of AsGa are chosen, and if implanted (as described above) in the Ge of the first layer 1, and then transferring the remainder 1′ of the Ge and the second layer 2 of AsGa to a host wafer 20 by means of an electrically insulating surface, and then by selectively removing the remainder 1″ of Ge by using known selective etching techniques.

Similarly, a structure GaN-on-insulator can be for example manufactured from a donor wafer 10 comprising a first layer 1 made of SiC or Si (111) and a second layer 2 made of GaN. One or several stop layers made of AlGaN and/or AIN may possibly be provided in the GaN layer. After removal of the second layer 2 made of GaN, a selective etching comprising the removal of the GaN located above the stop layer can be used. Thus, for example, dry etching using a plasma gas comprising CH₂, H₂ and possibly Ar, can etch the GaN quicker than AlN. The stop layer can be removed if desired to obtain finally a layer of GaN with little surface roughness and very homogeneous thickness. In the same way, the method according to the invention can be adapted to other transfer layers in group III-V or II-VI alloys. Also, all of these materials can include carbon in small quantities (around 5%) or doping agents.

What is claimed is:

1. A method of forming a semiconductor structure, which comprises:
forming a zone of weakness in a donor wafer made of a semiconductor material comprising germanium to define a layer that includes germanium to be transferred, by co-implanting at least two different atomic species into the donor wafer;
bonding the donor wafer to a host wafer to form a combined structure; and
supplying energy to the donor wafer by performing a thermal treatment at a temperature between 300° C. and 400° C. for a period of from 30 minutes to four hours to weaken the donor wafer at the zone of weakness for subsequent transfer to the host wafer.

2. The method of claim 1, wherein the thermal treatment is carried out at a temperature of between 325° C. and 375° C. for approximately two hours.

3. The method of claim 1, wherein the supplying of energy is conducted at a temperature and for a time sufficient to lead to the detachment of the layer from the donor wafer and its transfer to the host wafer.

4. The method of claim 1, which further comprises supplying mechanical energy or additional thermal energy in an amount sufficient to detach the layer from the donor wafer and transfer it to the host wafer.

5. The method of claim 1, which further comprises plasma activating one of the donor wafer or the host wafer, or both, prior to bonding to strengthen the resulting bond between the two wafers in the combined structure.

6. The method of claim 1, wherein the two different atomic species that are co-implanted are helium and hydrogen.

7. The method of claim 6, wherein the helium and hydrogen are co-implanted at respective dosages with the helium dose representing 30% to 70% of the total dose.

8. The method of claim 1, after transfer, the layer has low/high frequency roughnesses that are lower than about 15 Å RMS/30 Å RMS, respectively, when measured by 500 micron profilometry/2*21 μm² AFM.

9. The method of claim 1, which further comprises treating the layer after transfer.

10. The method of claim 9, wherein the transfer layer is treated by an etching operation to reduce its thickness.

11. The method of claim 10, wherein the etching operation is carried out as part of or during a sacrificial oxidation operation.

12. The method of claim 11, wherein the donor wafer includes a second material different from the material of the layer, and part of the second material is transferred with the layer, with the etching operation that is conducted being a selective etching of the second material that is transferred to the host wafer.

13. The method of claim 12, which further comprises conducting a sacrificial oxidation of at least a part of the layer before selective etching to strengthen the bond between the layer and host wafer.

14. The method of claim 1, which further comprises growing crystalline material on the layer after transfer to the host wafer.

15. The method of claim 1, wherein the layer is made of Si₁₋ₓGeₓ with 0<x≦1 and (a) the donor wafer further comprises a second layer of elastically strained Si, or (b) donor wafer comprises a support substrate made of bulk Si, a buffer structure made of SiGe, a second layer of strained Si or (c) the donor wafer comprises a second layer made of strained Si and a third layer made of Si₁₋ₓGeₓ on the second layer.

16. The method of claim 15, which further comprises, after transfer of the Si₁₋ₓGeₓ layer, selective etching of the remaining part of that with respect to the second layer.

17. The method of claim 15, wherein the donor wafer comprises a support substrate made of bulk Si, a buffer structure made of SiGe, and a multi-layer structure alternatively comprising layers of Si₁₋ₓGeₓwith 0<x≦1 and second layers of strained Si, so that multiple layers can be transferred from the donor wafer.

18. The method of claim 15, which further comprises forming of the strained layer at a deposit temperature of between around 450° C. (842° F.) and around 650° C. (1,202° F.) prior to forming the zone of weakness in the donor wafer.

19. The method of claim 15, which further comprises forming a bonding layer on the donor wafer, the host wafer, or on both prior to binding the wafers together, with the bonding layer comprising an electrically insulating material.

20. The method of claim 1 wherein the structure that is formed is a semiconductor-on-insulator structure of sSI, SGOI, SiGeOI or GeOI.

21. A semiconductor on insulator structure comprising a surface layer bonded to a host wafer with the surface layer having low/high frequency roughnesses that are lower than about 15 Å RMS/30 Å RMS, respectively, when measured by 500 micron profilometry/2*2 μm² AFM at any place on its surface.
